(19) United States
(12) Patent Application Publication
(10) Pub. No.: US 2009/0058447 A1
(43) Pub. Date: Mar. 5, 2009

(54) FAULT ANALYZER

(75) Inventor: Renzoh ORIMOTO, Beppu-shi (JP)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/199,497

(22) Filed: Aug. 27, 2008

(30) Foreign Application Priority Data
Aug. 27, 2007 (JP) 2007-219201

(51) Int. Cl. G01R 31/26

(52) U.S. Cl. 324/761

(57) ABSTRACT

The objective of the invention is to provide a type of fault analyzer and a method therefore that can easily specify fault locations in semiconductor devices. Fault analyzer 100 has the following parts: supporting member 110 for supporting sample S, a pair of upper probe pins 120 arranged above supporting member 110, a pair of lower probe pins 130 arranged below supporting member 110, lower-portion manipulator 140, which anchors the pair of lower probe pins 130 and which can move in the x, y and z directions of the lower probe pins 130, mirror 150, which is arranged below the supporting member 110 and reflects the image of the bottom surface of sample S supported on supporting member 110, optical microscope 160, which receives the reflected light of mirror 150 and shows an enlarged image of the bottom surface of sample S, magnet 170 mounted on the lower end of lower-portion manipulator 140, and base plate 180 that anchors magnet 170.

### FIELD OF THE INVENTION

The present invention pertains to a type of fault analyzer for performing fault analysis of semiconductor devices. Especially, the present invention pertains to a type of fault analyzer that can specify a fault location that is present in a BGA or other semiconductor device for surface mounting.

### BACKGROUND OF THE INVENTION

With progress in efforts to increase the scale of semiconductor integrated circuits, the design rule has become finer. Also, in order to increase the assembly density in the package, plural semiconductor chips are mounted in each package. In order to realize good mass production and a high yield of semiconductor devices, it is necessary to analyze the faults that occur in the semiconductor devices and to develop a manufacturing process to correct the faults.

According to a typical fault analysis of a semiconductor device in the prior art, probe pins are brought into contact with selected fine regions on the semiconductor device to check the electrical characteristics. An optical microscope is used for positioning the probe pins. The technology for positioning probes and semiconductor devices, for example, is described in Patent Reference 1 Japanese Kokai Patent Application No. Hei 10[1998]-116866.

In the prior art, the device for checking or analyzing the fault locations in semiconductor devices has the following parts: a stage for carrying the semiconductor device as a sample, probe pins, a manipulator for moving the probe pins in the x, y and z directions, and an optical microscope for positioning the probe pins in the semiconductor device. This device performs checking by having the probe pins contact one surface side of the semiconductor device.

FIG. 6 is a schematic cross-sectional view illustrating a typical BGA-type semiconductor device. As shown in the figure, semiconductor chip 12 is carried on the outer surface of substrate 10, and electrodes 14 on semiconductor chip 12 are connected via bonding wires 16 to wiring pattern 18 on the surface of the substrate. On the inner surface of substrate 10, electroconductive lands 20 are formed. The electroconductive lands 20 are connected via current paths inside the substrate to wiring pattern 18 on the outer surface of the substrate, and, at the same time, they are connected to solder balls 22 as external connecting terminals. The outer surface of substrate 10 containing semiconductor chip 12, bonding wires 16, etc., is molded with resin 24.

Faults that occur in the semiconductor device may be roughly classified into those of the semiconductor chip itself and those outside the semiconductor chip. Examples of the former type include wire breakage and short-circuiting of the internal wiring layer of the chip that forms the semiconductor integrated circuit. For the faults, fault locations inside the semiconductor chip can be specified by having probe pins contact the electrodes and wiring layer from the outer surface of the semiconductor chip after grinding of the molding resin.

As shown in FIG. 7, examples of the latter faults include a step joining fault F1 between wiring pattern 18 on the substrate outer surface and a bonding wire 16, fault F2 caused by damage to via-contact 28 that forms a current path inside the multilayered wiring substrate, fault F3 of wire breakage of wiring pattern 30 inside the substrate, fault F4 of joints between electroconductive lands 20 and solder balls 22, etc. These fault locations cannot be specified by checking of the probe pins from one direction.

The objective of the present invention is to solve the aforementioned problems of the prior art by providing a type of fault analyzer and fault analysis method that can easily specify fault locations in semiconductor devices.

### SUMMARY OF THE INVENTION

The present invention provides a checking method characterized by the following facts: the checking method is for a type of semiconductor device comprising a substrate, which contains a first principal surface containing first electroconductive regions, a second principal surface facing the first principal surface and containing second electroconductive regions, and current paths going through from the first electroconductive regions to the second electroconductive regions, at least one semiconductor chip carried on the first principal surface, electroconductive connecting members connecting the electrodes of the semiconductor chip and the first electroconductive regions, and external connecting terminals connected to the second electroconductive regions on the second principal surface; in this checking method, there are the following operation steps: a step in which a first probe pin is brought into contact with any of the first electroconductive regions, the electroconductive connecting members, and the current paths in the substrate from the first principal surface side of the substrate, and a second probe pin is brought into contact with an external connecting terminal from the second principal surface side of the substrate, and a step in which current is made to flow between the first probe pin and the second probe pin.

As a preferable checking method, the checking method also has the following step: when the semiconductor chip is resin sealed on the first principal surface of the substrate, at least the resin is removed to expose the electroconductive connecting members, the first electroconductive regions, or the current paths in the substrate. When the current paths in the substrate are exposed, it is possible to remove a layer contained in the resin to expose the elements that form the desired current paths. Also, the current paths in the substrate contain wiring patterns or via-contacts contained in a multilayered wiring substrate.

As a preferable scheme, the exposure step includes plural operation steps, that is, with the first exposure, the electroconductive connecting members or the first electroconductive regions are exposed, and, with the second exposure, the current paths in the substrate are exposed. Also, when plural semiconductor chips are laminated onto the first principal surface of the substrate, in the exposure step, the electroconductive connecting members of each semiconductor chip are exposed. The electroconductive connecting members include bonding wires connecting electrodes of a semiconductor chip and the first electroconductive regions. The electroconductive connecting members include contact members when the electrodes of the semiconductor chip are flip-chip joined to the first electroconductive regions. A preferable checking method also includes a step in which current is applied n to flow between the first and second probe pins so as to specify a fault location generated between the electroconductive connecting members, the first electroconductive regions, the current paths in the substrate, and the external connecting terminals.

The present invention provides a type of checking device characterized by the fact that the checking device for checking semiconductor devices has the following parts: a supporting member that supports a sample, a first probe pin arranged above the supporting member, a first positioning means, which can drive the first probe pin to move in the x, y and z directions and which positions the first probe pin so that the first probe pin contacts the selected electroconductive region on a first surface side of the sample, a second probe pin arranged beneath the supporting member, a second positioning means, which can drive the second probe pin to move in the x, y and z directions and which positions the second probe so that the second probe pin contacts the selected electroconductive region on a second surface side facing the first surface of the sample, and a means for feeding current between the first and second probe pins.

As a preferable scheme, the second positioning means includes a mirror arranged beneath the supporting member that reflects the image on the second surface side of the sample, and a microscope into which the image reflected by the mirrors input. The checking device also includes a presenting means that presents the presence/absence of a fault location in the sample corresponding to the current flowing between the first and second probe pins.

### BRIEF DESCRIPTION OF THE DRAWINGS

FIG. 1 is a schematic diagram illustrating the constitution of a fault analyzer in an embodiment of the present invention.

FIG. 2 is a diagram illustrating an example of the constitution for switching the probe pins in the fault analyzer in the present embodiment.

FIG. 3 is a diagram illustrating the fault analysis method using the fault analyzer in the present embodiment.

FIG. 4 is a diagram illustrating a preferable example of the fault analysis method in the present embodiment.

FIG. 5 is a diagram illustrating examples of semiconductor devices on which the fault analysis method of the present embodiment is adopted.

FIG. 6 is a cross-sectional view illustrating a typical constitution of a BGA-type semiconductor device.

FIG. 7 is a diagram illustrating topics to be addressed for the fault analysis method in the prior art.

### REFERENCE NUMERALS AND SYMBOLS AS SHOWN IN THE DRAWINGS

In the figures, 10 represents a substrate, 12 represents a semiconductor chip, 14 represents an electrode, 16, 16a represents a bonding wire, 18 represents a wiring pattern, 20 represents an electroconductive land, 22, 22a, 22b, 22c represents a solder ball, 24 represents a molding resin, 27, 29, 30 represents a wiring pattern, 26, 28 represents a via-contact, 100 represents a fault analyzer, 110 represents a supporting member, 120, 120a, 120b represents upper probe pins, 130, 130a, 130b represents lower probe pins, 140 represents a lower-portion manipulator, 150 represents a mirror, 160 represents an optical microscope, 170 represents a magnet, 180 represents a base plate, 200 represents a first switch, and 210 represents a second switch.

### DESCRIPTION OF THE EMBODIMENTS

According to the present invention, it is easy to specify fault locations in a semiconductor device by having the first probe contact the first principal side surface of the substrate and having the second probe contact the second principal surface of the substrate.

A preferred embodiment of the present invention will be explained in more detail below.

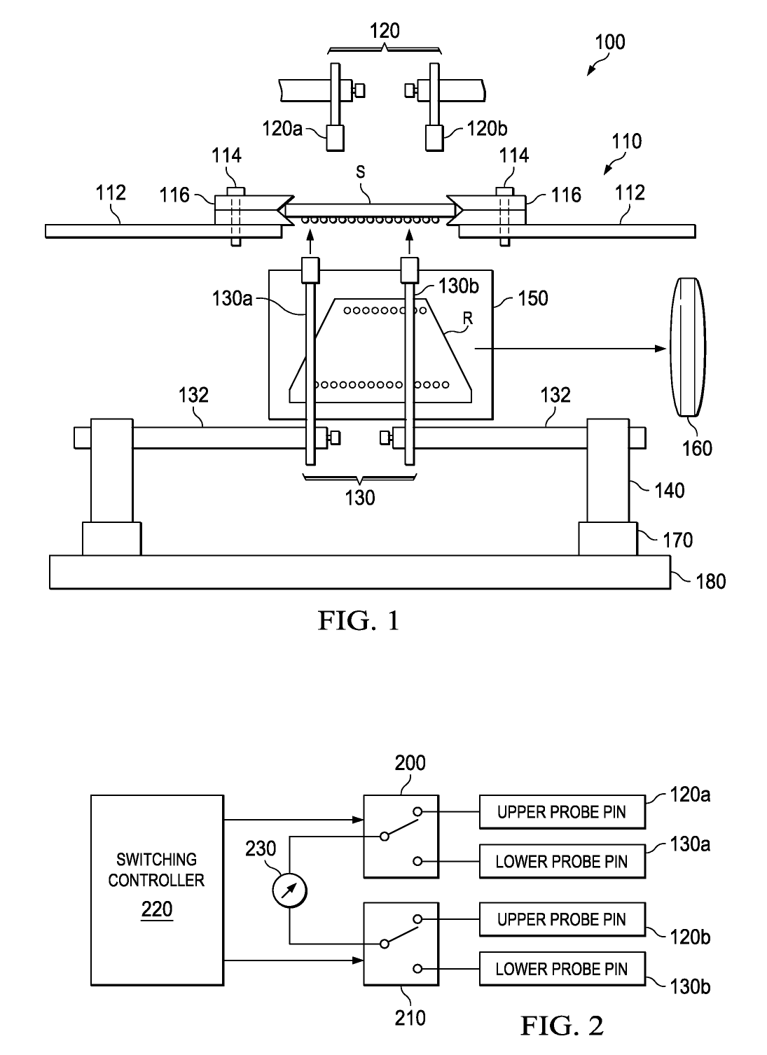

FIG. 1 is a schematic diagram illustrating the fault analyzer of a semiconductor device pertaining to an embodiment of the present invention. In this embodiment, fault analyzer 100 has the following parts: supporting member 110 for supporting sample S, a pair of upper probe pins 120 arranged above supporting member 110, a pair of lower probe pins 130 arranged below supporting member 110, lower-portion manipulator 140, which anchors the pair of lower probe pins 130 and which can move in the x, y and z directions of the lower probe pins 130, mirror 150, which is arranged below the supporting member 110 and reflects the image of the bottom surface of sample S supported on supporting member 110, optical microscope 160, which receives the reflected light of mirror 150 and shows an enlarged image of the bottom surface of sample S, magnet 170 mounted on the lower end of lower-portion manipulator 140, and base plate 180 that anchors magnet 170. Although not shown in the figure, fault analyzer 100 also has an upper-portion manipulator that can move the upper probe pins 120 in the x, y and z directions, and an optical microscope for aligning upper probe pins 120 with sample S.

The supporting member 110 has a pair of supporting plates 112 made of aluminum or another metal, and a pair of clamps 116 anchored by screws 114 on supporting plates 112. The clamps 116 are formed by superposing plates having inclined end surfaces to form opposite surfaces with a linear recession shape towards the center. The opposite side surfaces of sample S, that is, the semiconductor device, are held by the opposite surfaces of clamps 116, and sample S is supported nearly parallel to supporting plates 112.

The upper probe pins 120 and lower probe pins 130 have the same constitution. Each of them preferably has a sleeve made of an electroconductive metal and a tip portion engaged by a spring that is attached such that it can slide in the axial direction inside the sleeve. When contacting the region of sample S for checking, the tip portion moves in the axial direction against the force of the spring, and it applies a prescribed contact pressure on the region for checking. The upper probe pins 120 include a pair of probe pins 120a, 120b. One of them is used as a terminal for feeding an electric signal, and the other is used as a grounding terminal. Similarly, lower probe pins 130 include a pair of probe pins 130a, 130b. One of them is used as a terminal for feeding an electric signal, and the other is used as a grounding terminal. The upper probe pins 120 and/or lower probe pins 130 are used selectively, corresponding to the fault analysis of sample S as will be explained later.

The lower-portion manipulator 140 is made of iron or another electroconductive metal, and it has a pair of arms 132 for supporting lower probe pins 130. The lower-portion manipulator 140 can move directionally in three dimensions so that lower probe pins 130 anchored on arms 132 are positioned in the selected region of sample S for checking. The lower-portion manipulator 140 is anchored via magnet 170 on base plate 180. Just like the lower probe pins 130, the upper probe pins 120 are supported on an upper-portion manipulator not shown in the figure. As a result, positioning is performed on the region for checking from above sample S.

The mirror 150 is mounted inclined at about 45-60° below supporting member 110. The mirror 150 reflects image R of the bottom surface of sample S onto optical microscope 160. By means of the optical microscope 160, while an enlarged image of the bottom surface of sample S is viewed, lower probe pins 130 are matched to the selected region for checking of the bottom surface of sample S.

FIG. 2 is a diagram illustrating an example of the constitution for switching the probe pins in the fault analyzer. The fault analyzer in this embodiment allows checking of the electrical characteristics of sample S using only upper probe pins 120, checking of the electrical characteristics of sample S using only lower probe pins 130, and checking of the electrical characteristics of sample S using both an upper probe pin 120 and a lower probe pin 130. As shown in FIG. 2, fault analyzer 100 has first switch 200, second switch 210, and switching controller 220 for controlling the first and second switches. The switching controller 220, for example, controls first switch 200 and second switch 210 corresponding to input from the user or output from another circuit.

When checking is performed using upper probe pins 120, the first switch 200 selects upper-portion probe pin 120a as the terminal on the electrical signal supply side, and second switch 210 selects upper-portion probe pin 120b as the terminal on the grounding side. Also, the upper-portion probe pin 120a and upper-portion probe pin 120b may be swapped. When checking is performed using lower probe pins 130, the first switch 200 selects lower-portion probe pin 130a as the terminal on the signal supply side, and second switch 210 selects lower-portion probe pin 130b as the terminal on the grounding side. Also, the lower-portion probe pin 130a and lower-portion probe pin 130b may be swapped.

When both upper probe pins 120 and lower probe pins 130 are used for checking, first switch 200 selects upper-portion probe pin 120a as the terminal on the signal supply side, and second switch 210 selects lower-portion probe pin 130b as the terminal on the grounding side. Also, the upper-portion probe pin 120a and lower-portion probe pin 130b may be swapped. In this way, prescribed current 230 is applied to flow between the probe pin of a terminal on the signal supply side and the probe pin of a terminal on the grounding side. It is preferred that the fault analyzer assess the state as wire breakage or another open fault when no current flows between the probe pins, and that it assess the state as a short circuit fault when a current over the threshold current flows between the probe pins. In addition, the fault analysis result can be presented on a display unit or the like.

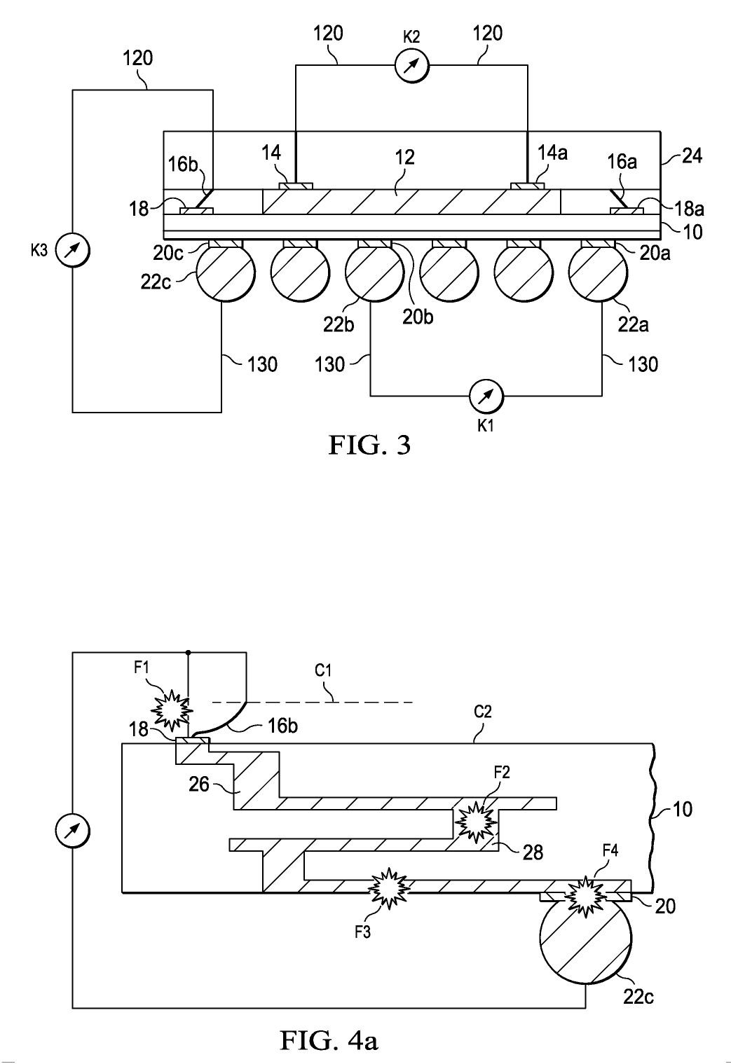

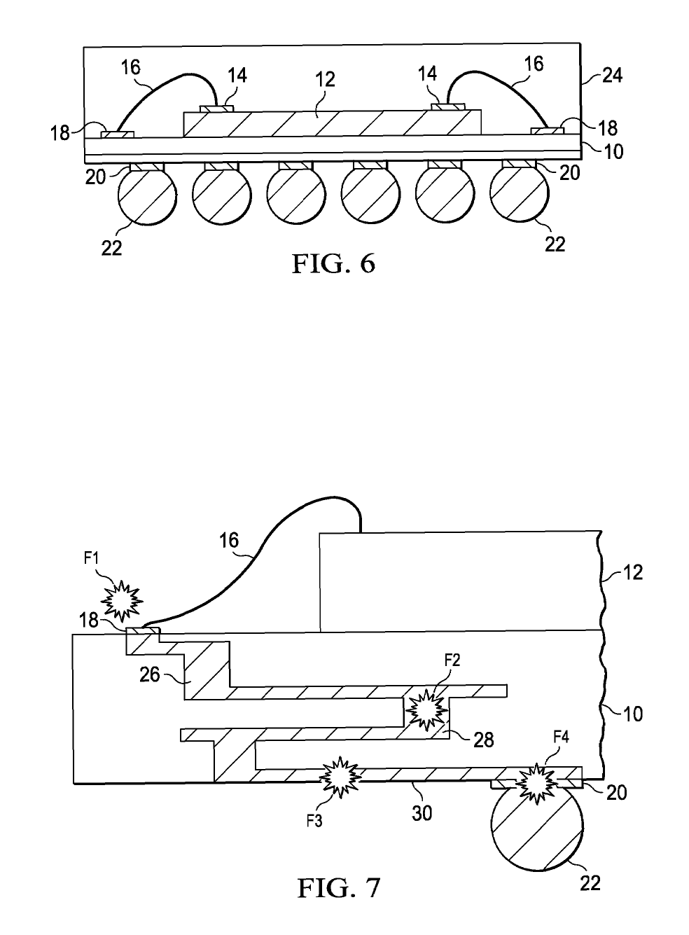

In the following, an explanation will be given regarding a fault analysis method using the fault analyzer in this embodiment. FIG. 3 is a diagram illustrating a typical fault analysis method of a BGA-type semiconductor device. As first fault analysis K1, as shown in FIG. 6, the BGA-type semiconductor device is taken as sample S as-is, and it is mounted on supporting member 110. Then, lower probe pins 130 are brought into contact with selected solder balls 22a, 22b on the inner surface of sample S, and current is applied between lower probe pins 130. The applied current flows from solder ball 22a through electroconductive land 20a, a current path inside the substrate, wiring pattern 18a on the substrate outer surface, bonding wire 16a, electrode 14a on the semiconductor chip, and the integrated circuit in the semiconductor chip, and again to electrode on the semiconductor chip, a bonding wire, the wiring pattern on the outer surface of the substrate, a current path within the substrate, and electroconductive land 20b to solder ball 22b. As a result, it is possible to check the presence/absence of faults in the overall current paths of the device including semiconductor chip 12, bonding wires 16, substrate 10 and solder balls 22. For first fault analysis K1, however, if there is wire breakage or short-circuiting a fault in certain portions of the overall current path of the device, it is impossible to specify the fault location.

As shown in FIG. 3, for second fault analysis K2, molding resin 24 is ground, and sample S is processed so that at least electrodes 14 of semiconductor chip 12 are exposed. The upper probe pins 120 are used in this case. The upper probe pins 120 are brought into contact with selected electrodes 14 of semiconductor chip 12, and current is fed to flow between the probe pins to check the electrical characteristics of semiconductor chip 12. Of course, in this case, in addition to contact between upper probe pins 120 and electrodes 14, it is also possible to remove the wiring layer and insulating layer that form semiconductor chip 12, and to have the upper-portion probe pins contact the wiring layer in the semiconductor chip. Based on second fault analysis K2, the fault location in semiconductor chip 12 can be specific. However, when faults are present outside the semiconductor chip, that is, when faults F1-F4 pertaining to the bonding wires and substrate are present as shown in FIG. 7, it is impossible to specify the fault locations. Here, in addition to grinding, molding resin 24 may also be removed by means of decapitation or the like.

As third fault analysis K3, the molding resin 24 is ground, and sample S with necessary regions exposed is attached on supporting member 110, and, from above and below sample S, an upper probe pin 120 and a lower probe pin 130 are brought into contact with the regions for checking, and faults generated outside the semiconductor chip can be analyzed. As shown in FIG. 3, upper probe pin 120 is brought into contact with selected bonding wire 16b, and lower probe pin 130 is brought into contact with selected solder ball 22c.

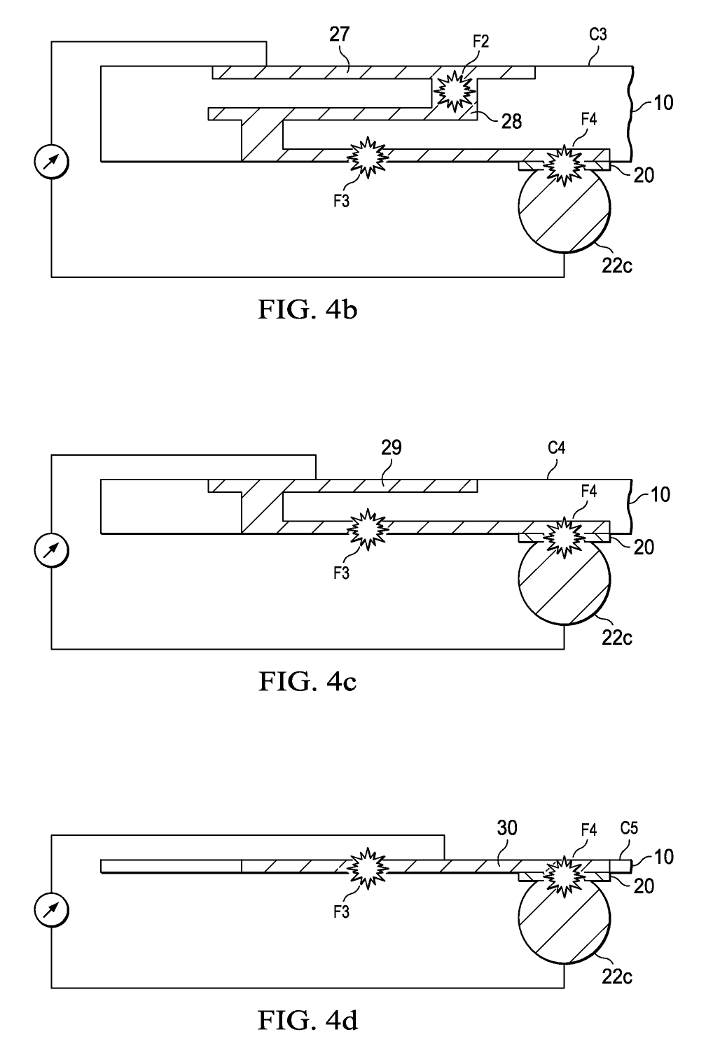

In the following, an explanation will be given in more detail regarding the third fault analysis K3 with reference to FIG. 4. As shown in FIG. 4(a), it is assumed that open faults F1-F4 exist in the current path between selected bonding wire 16b and selected solder ball 22c. The information concerning the presence/absence of the faults can be obtained from an operating test performed before the fault analysis. In the operating test, expected conduction between the solder balls should be realized, and the solder balls pertaining to the fault locations are specified.

First of all, the molding resin is ground down to ground surface C1, and sample S in this state is mounted on supporting member 110. The upper probe pin 120 is brought into contact with bonding wire 16b exposed on ground surface C1, and lower probe pin 130 is brought into contact with solder ball 22c. Because one of the faults of faults F1-F4 is present in the current path, no current flows between the probe pins.

Then, molding resin 24 of sample S is ground down to ground surface C2. The ground surface C2 is the position where the substrate surface is exposed. The upper probe pin 120 is brought into contact with wiring pattern 18 exposed on ground surface C2, and lower probe pin 130 is brought into contact with solder ball 22c. In this case, if current flows between the probe pins, it is specified (estimated) that fault F1 exists between wiring pattern 18 on the surface of the substrate and bonding wire 16b. If no current flows, it is specified (estimated) that the joint between wiring pattern 18 and bonding wire 16b is normal, and one of the faults of faults F2-F4 is present in the current path between wiring pattern 18 and solder ball 22c.

Then, as shown in FIG. 4(b), the substrate is ground down to ground surface C3. Then, upper probe pin 120 is brought into contact with wiring pattern 27 exposed on ground surface C3, and lower probe pin 130 is brought into contact with solder ball 22c. If no current flows between the probe pins, it is specified (estimated) that via-contact 26 between wiring pattern 18 and wiring pattern 27 is normal, and faults F2-F4 are present in the current path between wiring pattern 27 and solder ball (22c).

Then, as shown in FIG. 4(c), the substrate is ground down to ground surface C4, and upper probe pin 120 is brought into contact with wiring pattern 29 exposed on ground surface C4. The lower probe pin 130 is brought into contact with solder ball 22c. If a current flows between the probe pins, it is specified (estimated) that fault F2 exists in via-contacts 28. On the other hand, if no current flows between the probe pins, it is specified (estimated) that fault F3 or fault F4 exists in the current path between wiring pattern 29 and solder ball 22c.

Then, as shown in FIG. 4(d), the substrate is ground down to ground surface C5. The upper probe pin 120 is brought into contact with wiring pattern 30 exposed on ground surface C5, and lower probe pin 130 is brought into contact with solder ball 22c. If current flows between the probe pins, it is specified (estimated) that fault F3 exists in wiring pattern 30. On the other hand, if no current flows, it is specified (estimated) that fault F4 exists between wiring pattern 30 and solder ball 22c or between electroconductive land 20 and solder ball (22c).

As explained above, by using both an upper-portion probe pin and a lower-portion probe pin to check the electrical characteristics from above and below sample S, it is easy to specify (estimate) various types of fault generated in the semiconductor device, which task is impossible with the fault analyzer in the prior art. The fault locations shown in FIG. 4 are merely examples shown to facilitate understanding. The present invention is not limited to this scheme. Faults are not limited to open faults; short circuits and other faults are also included. When short-circuiting takes place, because the current flowing between the open pins is over the threshold, it is easy to assess the fault.

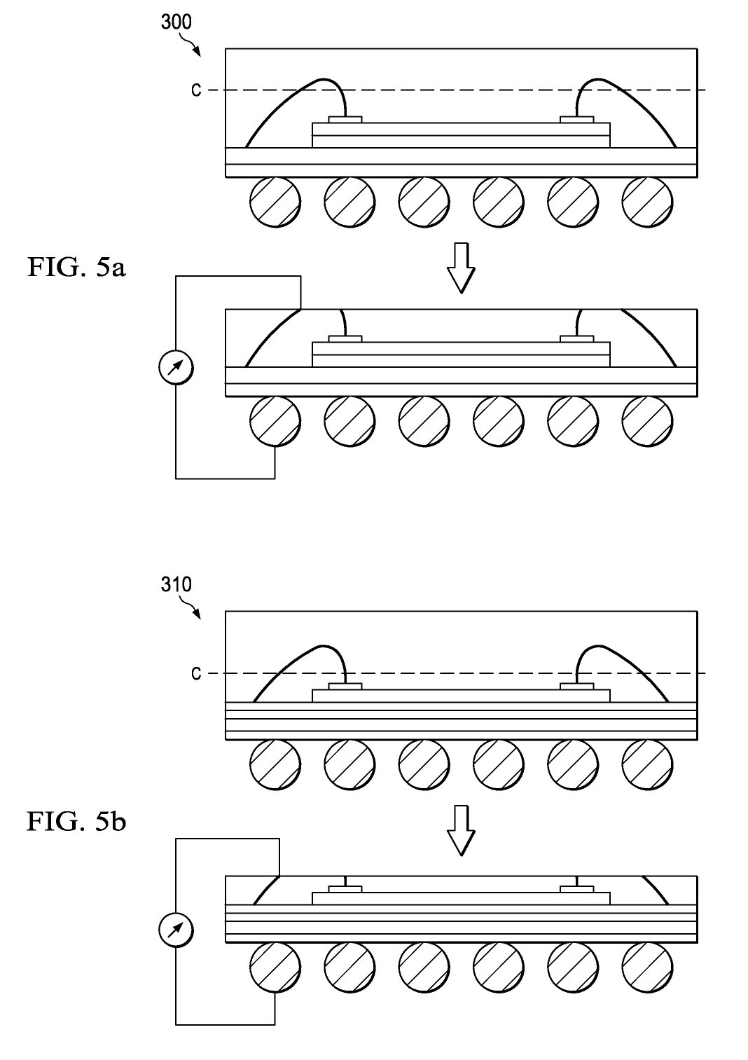

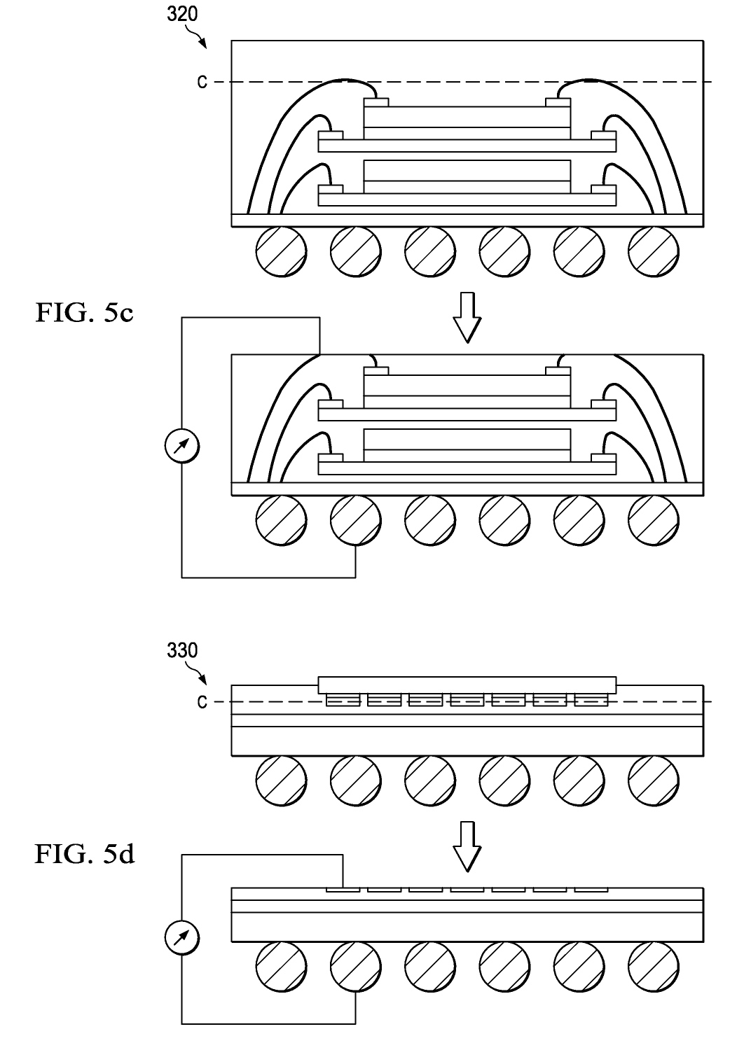

FIG. 5 is a diagram illustrating a few examples of semiconductor devices on which the fault analysis method in this embodiment can be adopted. The figures on the left show various types of semiconductor devices and their ground surfaces C. The figures on the right show states in which an upper-portion probe pin is brought into contact with member exposed on ground surface C, and a lower-portion probe pin is brought into contact with a solder ball.

Semiconductor device 300 shown in FIG. 5(a) is a typical BGA-type semiconductor device, with a semiconductor chip carried on the upper surface of a substrate, and with plural solder balls carried on its lower surface. When checking is performed using both an upper-portion probe pin and a lower-portion probe pin, the molding resin of the semiconductor device is ground down to ground surface C. In order to expose the elements that can form the current paths of semiconductor device 300 appropriately, the grinding operation may be performed in plural operation steps or in plural rounds.

Semiconductor device 310 shown in FIG. 5(b) is a semiconductor device for surface mounting with a multilayered wiring structure of 2, 4 or more layers. When checking is performed for the current paths in a multilayered wiring structure, after the molding resin is ground or removed, a layer of the multilayered wiring substrate is ground or removed, and it is possible to expose the desired wiring pattern or via-contacts contained in the multilayered wiring substrate.

Semiconductor device 320 shown in FIG. 5(c) is a multi-chip type of semiconductor device having plural semiconductor chips carried on a substrate. When plural semiconductor chips are laminated, the bonding wires may cross each other with short circuiting taking place. In such case, the molding resin is ground until the bonding wires are exposed for each semiconductor chip, and it is easy to specify the fault location where the bonding wires cross each other.

Semiconductor device 330 shown in FIG. 5(d) has flip chip joints facing and connecting the circuit surface or electrode surface of a semiconductor chip on a substrate. The outer surface of the semiconductor chip may be exposed from the sealing resin. Here, the upper-portion probe pin and lower-portion probe pin are brought into contact with an electrode or wiring pattern of the outer surface of the substrate and a selected solder ball on the inner surface of the substrate, respectively, and it is possible to specify fault locations in the current paths between the substrate and the solder balls.

In the embodiment, the upper-portion probe pin is brought into contact with the ground surface side of the semiconductor device (the sample), and the lower-portion probe pin is brought into contact with the solder ball side of the semiconductor device. However, the opposite configuration may also be adopted, that is, the lower-portion probe pin is brought into contact with the ground surface side, and the upper-portion probe pin is brought into contact with the solder ball side. Also, grinding for exposure may also be performed from the solder ball side, with the upper-portion probe pin and lower-portion probe pin being brought into contact, respectively.

In the embodiment, fault analysis of a BGA-type semiconductor device has been presented as an example. However, the present invention is not limited to this. One may also adopt the invention in other types of semiconductor devices for surface mounting, with plural external connecting terminals set in rows on one surface of the substrate. The shape of the external connecting terminals is not limited to a ball shape. Also, the external connecting terminals may be of a type that does not protrude from the bottom surface of the package, such as an LGA type.

In the embodiment, the upper-portion probe pins and the lower-portion probe pins each include a pair of probe pins. However, the present invention is not limited to this scheme. There may be more probe pins. For example, by allotting plural probe pins to plural terminals for feeding electric signals, it is possible to execute checking of a variety of electrical characteristics. In addition, it is also possible to allot preparatory probe pins.

A preferable embodiment of the present invention was explained above. However, the present invention is not limited to the embodiment. As long as the gist of the present invention described in the claims is observed, various modifications or changes can be made.

I claim:

1. A method for fault-checking a type of semiconductor device having a substrate, which contains a first principal surface containing first electro-conductive regions, a second principal surface facing the first principal surface and containing second electroconductive regions, and current paths going through from the first electroconductive regions to the second electroconductive regions, a semiconductor chip carried on the first principal surface, electroconductive connecting members connecting the electrodes of the semiconductor chip and the first electroconductive regions, and external connecting terminals connected to the second electroconductive regions on the second principal surface; comprising:
bringing a first probe pin into contact with a first electro-conductive region, or an electroconductive connecting members, or a current path in the substrate from the first principal surface side of the substrate;
bringing a second probe pin into contact with an external connecting terminal from the second principal surface side of the substrate,
reading an amount of electrical current flowing between the first probe pin and the second probe pin to estimate the location of a fault in the semiconductor device.

2. The method described in claim 1, further comprising a step of removing a resin and exposing the electroconductive connecting members, or the first electroconductive regions, or the current paths in the substrate.

3. The method described in claim 2, in which the current paths in the substrate contain wiring patterns and via-contacts in a multilayered wiring substrate.

4. The method described in claim 2, in which the exposing step includes plural operation steps, that is, with a first exposure, the electroconductive connecting members or the first electroconductive regions are exposed, and, with a second exposure, the current paths in the substrate are exposed.

5. The method described in claim 2, in which the semiconductor chip comprises plural semiconductor chips laminated onto the first principal surface of the substrate, and the exposing step further exposes the electroconductive connecting members of each semiconductor chip.

6. The checking method described in claim 1, in which the electroconductive connecting members include bonding wires connecting electrodes of the semiconductor chip and the first electroconductive regions.

7. The checking method described in claim 1, in which the electroconductive connecting members include contact members when the electrodes of the semiconductor chip are flip-chip joined to the first electroconductive regions.

8. A device; comprising
a supporting member that supports a sample,
a first probe pin arranged above the supporting member,
a first positioning means, which can drive the first probe pin to move in the x, y and z directions and which positions the first probe pin so that the first probe pin contacts the selected electroconductive region on the first surface side of the sample,
a second probe pin arranged beneath the supporting member,
a second positioning means, which can drive the second probe pin to move in the x, y and z directions and which positions the second probe so that the second probe pin contacts the selected electroconductive region on the second surface side facing the first surface of the sample,
and a means for feeding current between the first and second probe pins.

9. The device described in claim 8, in which the second positioning means includes a mirror arranged beneath the supporting member that reflects the image on a second surface side of the sample, and a microscope into which the image reflected by the mirrors input.

10. The device described in claim 9, further comprising a presenting means that presents the presence/absence of a fault location in the sample corresponding to an amount of current flowing between the first and second probe pins.
